(19) United States
(12) Patent Application Publication
(10) Pub. No.: US 2025/0194388 A1
(43) Pub. Date: Jun. 12, 2025

(54) DISPLAY DEVICE, METHOD FOR MANUFACTURING THE SAME, AND ELECTRONIC DEVICE INCLUDING THE SAME

(71) Applicant: Samsung Display Co., Ltd., Yongin-Si (KR)

(72) Inventors: HYUNMIN CHO, Yongin-si (KR); YUNJONG YEO, Yongin-si (KR); DAWOON JUNG, Yongin-si (KR); KYONG-CHOL LEE, Yongin-si (KR); YU-GWANG JEONG, Yongin-si (KR); JAEWOO JEONG, Yongin-si (KR)

(21) Appl. No.: 18/967,667

(22) Filed: Dec. 4, 2024

(30) Foreign Application Priority Data
Dec. 6, 2023 (KR) 10-2023-0175986

(51) Int. Cl. H10K 59/80; H10K 59/12; H10K 59/40

(52) U.S. Cl. CPC H10K 59/8792; H10K 59/1201; H10K 59/873; H10K 59/40

(57) ABSTRACT

A display device includes: a light emitting element disposed in a light emitting area on a substrate, a light transmission layer disposed on the light emitting element and defining a plurality of openings spaced apart from each other, a transparent layer contacting an upper surface of the light transmission layer and extending to an inside of the openings to contact at least a part of a side surface of the light transmission layer, and a plurality of light control patterns filling the openings.

### CROSS-REFERENCE TO RELATED APPLICATION

This application claims priority to and benefits of Korean Patent Application No. 10-2023-0175986 under 35 U.S.C. § 119, filed on Dec. 6, 2023 in the Korean Intellectual Property Office (KIPO), the entire contents of which are hereby incorporated by reference.

### BACKGROUND

### 1. Technical Field

Embodiments relate generally to a display device and a method of manufacturing the same. More particularly, embodiments relate to a display device the provides visual information and a method of manufacturing the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

The display device may display an image with a wide viewing angle, or the viewing angle of the image displayed on the display device may be limited for security reasons or to improve image reflection.

### SUMMARY

Embodiments provide a display device that can effectively control a viewing angle.

Embodiments provide a method of manufacturing the display device.

A display device according to embodiments of the present disclosure includes a light emitting element disposed in a light emitting area on a substrate, a light transmission layer disposed on the light emitting element and defining a plurality of openings spaced apart from each other, a transparent layer contacting an upper surface of the light transmission layer and extending to an inside of the openings to contact at least a part of a side surface of the light transmission layer, and a plurality of light control patterns filling the openings.

In an embodiment, the transparent layer may contact an entire side surface of the light transmission layer.

In an embodiment, the transparent layer may contact only a part of the side surface of the light transmission layer.

In an embodiment, a lower surface of the transparent layer facing the light emitting element and a lower surface of the light transmission layer facing the light emitting element may be located on a same plane.

In an embodiment, the transparent layer may include a silicon compound.

In an embodiment, an average thickness of the transparent layer may range from about 300 angstroms (Å) to about 3000 angstroms (Å).

In an embodiment, the transparent layer may include a conductive metal oxide.

In an embodiment, an average thickness of the transparent layer may range from about 30 angstroms (Å) to about 3000 angstroms (Å).

In an embodiment, the transparent layer may have a single-layer structure or a multi-layer structure.

In an embodiment, an etch rate of the light control patterns may be greater than an etch rate of the transparent layer.

In an embodiment, each of the light control patterns may have a cross-sectional shape that becomes narrower as a distance from the light emitting element increases.

In an embodiment, the display device may further include an encapsulation layer disposed between the light emitting element and the light transmission layer, and including at least one inorganic layer and at least one organic layer.

In an embodiment, the display device may further include a touch sensing layer disposed between the encapsulation layer and the light transmission layer.

In an embodiment, the light control patterns may include an organic material containing at least one selected from a group consisting of black pigment and black dye.

In an embodiment, the light transmission layer may include a transparent organic material.

A method of manufacturing a display device according to embodiments of the present disclosure, the method includes forming a light emitting element in a light emitting area on a substrate, forming a light transmission layer in which a plurality of openings spaced apart from each other are defined on the light emitting element, forming a transparent layer contacting an upper surface of the light transmission layer and extending to an inside of the openings to contact at least a part of a side surface of the light transmission layer, and forming a plurality of light control patterns filling the openings.

In an embodiment, in the forming the transparent layer, the transparent layer may be formed by chemical vapor deposition (CVD) or sputtering deposition.

In an embodiment, the transparent layer may be formed using silicon oxide or conductive metal oxide.

In an embodiment, the forming the plurality of light control patterns may include forming a preliminary light control pattern filling the openings and forming the plurality of light control patterns by removing a part of an upper part of the preliminary light control pattern through an ashing process. The forming the light transmission layer may include forming an organic layer on the light emitting element, forming a hard mask layer on the organic layer, forming photosensitive organic patterns on the hard mask layer, and simultaneously patterning the organic layer and the hard mask layer using the photosensitive organic patterns as a mask. In the ashing process, an etch rate of the light control patterns may be greater than an etch rate of the transparent layer.

An electronic device according to embodiments of the present disclosure includes a display device and a processor which controls the display device, the display device includes: a light emitting element disposed in a light emitting area on a substrate, a light transmission layer disposed on the light emitting element and defining a plurality of openings spaced apart from each other, a transparent layer contacting an upper surface of the light transmission layer and extending to an inside of the openings to contact at least a part of a side surface of the light transmission layer, and a plurality of light control patterns filling the openings.

A display device according to an embodiment of the present disclosure may include a light transmission layer in which a plurality of openings spaced apart from each other are defined, a transparent layer contacting an upper surface of the light transmission layer and extending to an inside of the openings to contact at least a part of a side surface of the light transmission layer, and a plurality of light control patterns filling the openings. Accordingly, the display device may not include a separate light blocking film that controls the viewing angle. In addition, the light efficiency of the display device may be improved, and the display device may control the viewing angle more effectively. In addition, mass productivity may be improved and process cost may be reduced.

In other embodiments, a display device according to an embodiment of the present disclosure may include a light transmission layer in which a plurality of openings spaced apart from each other are defined, a transparent layer contacting an upper surface of the light transmission layer and not contacting a side surface of the light transmission layer, and a plurality of light control patterns filling the transparent layer. Accordingly, the display device may not include a separate light blocking film that controls the viewing angle. In addition, mass productivity may be improved and process cost may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is an enlarged plan view of a part of a display area of the display device of FIG. 1.

FIG. 3 is a cross-sectional view taken along line I-I′ of FIG. 2.

FIG. 4 is a cross-sectional view illustrating an example of light control patterns, a light transmission layer, and a transparent layer of FIG. 3.

FIG. 5 is a plan view illustrating an example of light control patterns of FIG. 3.

FIGS. 6, 7, 8, 9, 10, 11, 12, and 13 are cross-sectional views illustrating some steps of a method of manufacturing the display device of FIGS. 3 and 4.

FIG. 14 is a cross-sectional view illustrating light control patterns, a light transmission layer, and a transparent layer of a display device according to an embodiment of the present disclosure.

FIG. 15 is a cross-sectional view illustrating light control patterns, a light transmission layer, and a transparent layer of a display device according to an embodiment of the present disclosure.

FIGS. 16, 17, 18, 19, 20, 21, and 22 are cross-sectional views for explaining some steps of a method of manufacturing the display device of FIGS. 3 and 15.

FIG. 23 is a plan view illustrating an example of light control patterns of FIG. 3.

FIG. 24 is a cross-sectional view illustrating a display device according to an embodiment of the present disclosure.

FIG. 25 is a block diagram illustrating an electronic device according to an embodiment of the present disclosure.

### DETAILED DESCRIPTION OF THE EMBODIMENTS

Hereinafter, a display device and a method of manufacturing the same according to embodiments of the present disclosure will be explained in detail with reference to the accompanying drawings. The same reference numerals are used for the same components in the drawings, and redundant descriptions of the same components will be omitted.

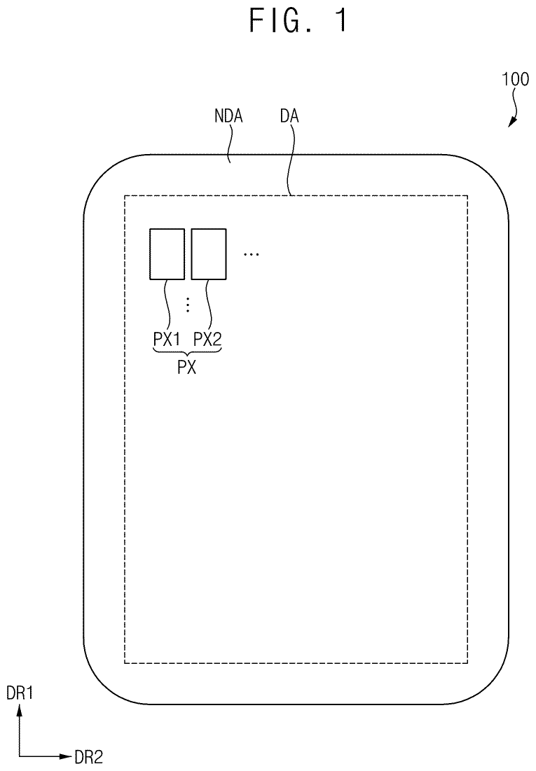

FIG. 1 is a plan view illustrating a display device 100 according to an embodiment of the present disclosure.

Referring to FIG. 1, the display device 100 according to an embodiment may include a display area DA and a non-display area NDA.

A plurality of pixels PX may be arranged in the display area DA. Each of the plurality of pixels PX may emit light. The plurality of pixels PX may include a first pixel PX1 and a second pixel PX2. For example, the first pixel PX1 and the second pixel PX2 may emit light at the same time. In other embodiments, when the first pixel PX1 emits light, the second pixel PX2 may not emit light. In other embodiments, when the first pixel PX1 does not emit light, the second pixel PX2 may emit light. As each of the plurality of pixels PX emits light, the display area DA may display an image.

The plurality of pixels PX may be repeatedly arranged along a first direction DR1 and a second direction DR2 intersecting the first direction DR1 in a plan view. For example, the second pixel PX2 may be adjacent to the first pixel PX1. Specifically, the second pixel PX2 may be adjacent to the first pixel PX1 in the second direction DR2.

The non-display area NDA may be located around the display area DA. For example, the non-display area NDA may surround at least a part of the display area DA. A driver may be placed in the non-display area NDA. The driver may provide signals and/or voltages to the plurality of pixels PX. For example, the driver may include a data driver, a gate driver, and the like. The non-display area NDA may not display image.

In this specification, a plane may be defined in the first direction DR1 and the second direction DR2. For example, the first direction DR1 may be perpendicular to the second direction DR2.

The display device 100 of the inventive concept may be an organic light emitting display device (OLED), a liquid crystal display device (LCD), a field emission display device (FED), a plasma display device (PDP), an electrophoretic display device (EPD), or an inorganic light emitting display device (ILED).

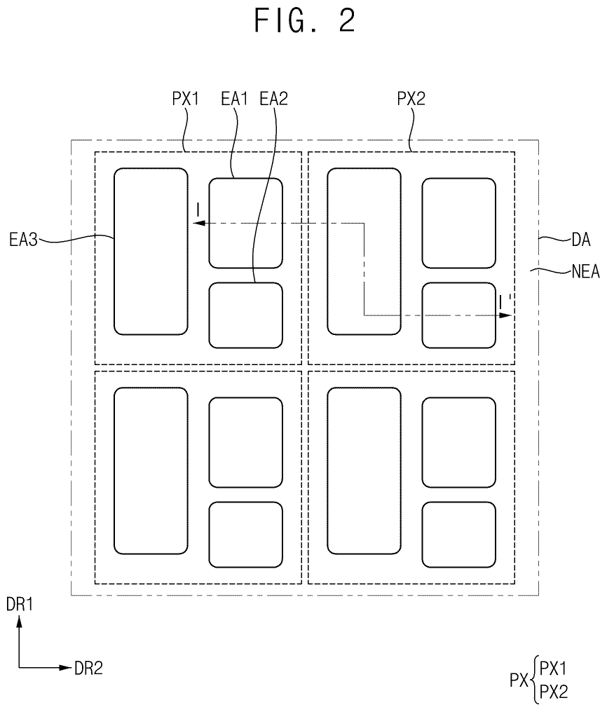

FIG. 2 is an enlarged plan view of a part of the display area DA of the display device 100 of FIG. 1.

Referring to FIGS. 1 and 2, as described above, the display device 100 may include the display area DA and the non-display area NDA, and the plurality of pixels PX may be disposed in the display area DA. The plurality of pixels PX may include the first pixel PX1 and the second pixel PX2.

Each of the first pixel PX1 and the second pixel PX2 may include a first light emitting area EA1, a second light emitting area EA2, a third light emitting area EA3, and a non-light emitting area NEA.

The first light emitting area EA1 may emit light of a first color, the second light emitting area EA2 may emit light of a second color, and the third light emitting area EA3 may emit light of a third color. In an embodiment, the first color may be red, the second color may be green, and the third color may be blue. As the first color light, the second color light, and the third color light are combined, each of the first pixel PX1 and the second pixel PX2 may emit light of various colors. However, embodiments of the present disclosure are not limited thereto. The non-light emitting area NEA may not emit light.

The area of the first light emitting area EA1 may be different from the area of the second light emitting area EA2 and the third light emitting area EA3, respectively. For example, the area of the third light emitting area EA3 may be larger than the area of the first light emitting area EA1, and the area of the first light emitting area EA1 may be larger than the area of the second light emitting area EA2. However, embodiments of the present disclosure are not limited thereto.

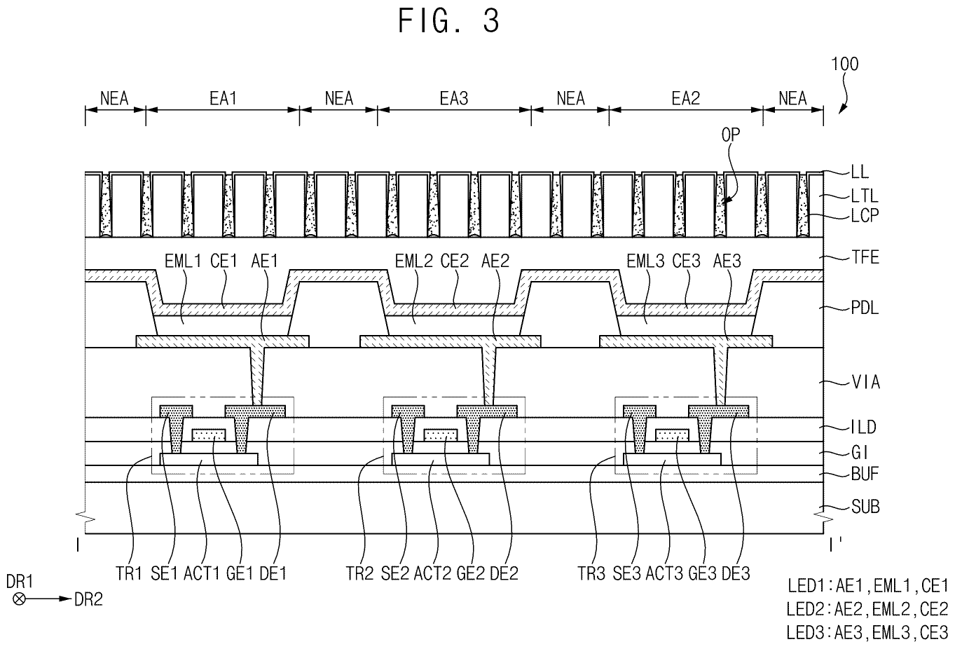

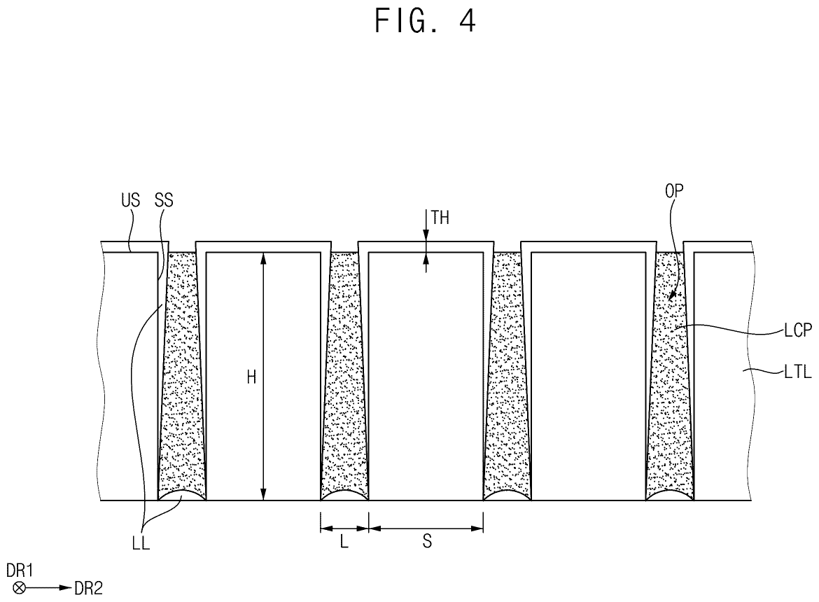

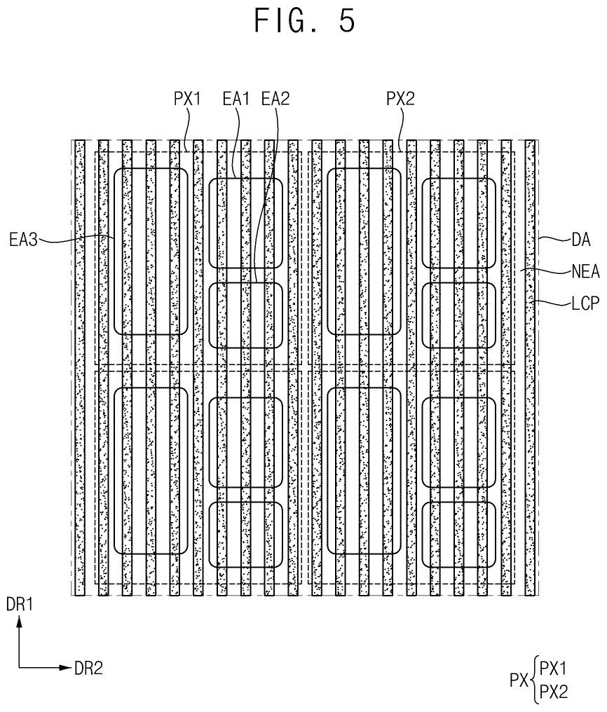

FIG. 3 is a cross-sectional view taken along line I-I′ of FIG. 2. FIG. 4 is a cross-sectional view illustrating an example of light control patterns LCP, a light transmission layer LTL, and a transparent layer LL of FIG. 3. FIG. 5 is a plan view illustrating an example of light control patterns LCP of FIG. 3.

Referring to FIGS. 3, 4, and 5, the display device 100 according to an embodiment of the present disclosure may include a substrate SUB, a buffer layer BUF, first, second, and third transistors TR1, TR2, and TR3, a gate insulation. layer GI, an interlayer insulating layer ILD, a via insulating layer VIA, a pixel defining layer PDL, first, second, and third light emitting elements LED1, LED2, and LED3, an encapsulation layer TFE, the plurality of light control patterns LCP, the transparent layer LL, and the light transmission layer LTL.

Here, the first transistor TR1 may include a first active pattern ACT1, a first gate electrode GE1, a first source electrode SE1, and a first drain electrode DE1. The second transistor TR2 may include a second active pattern ACT2, a second gate electrode GE2, a second source electrode SE2, and a second drain electrode DE2. The third transistor TR3 may include a third active pattern ACT3, a third gate electrode GE3, a third source electrode SE3, and a third drain electrode DE3.

In addition, the first light emitting element LED1 may include a first pixel electrode AE1, a first light emitting layer EML1, and a first common electrode CE1. The second light emitting element LED2 may include a second pixel electrode AE2, a second light-emitting layer EML2, and a second common electrode CE2. The third light emitting element LED3 may include a third pixel electrode AE3, a third light emitting layer EML3, and a third common electrode CE3.

The substrate SUB may include a transparent material or an opaque material. The substrate SUB may be made of a transparent resin substrate. Examples of the transparent resin substrate may include a polyimide substrate. In this case, the polyimide substrate may include a first organic layer, a first barrier layer, a second organic layer, and the like. In other embodiments, the substrate SUB may include a quartz substrate, synthetic quartz substrate, calcium fluoride substrate, F-doped quartz substrate, a soda-lime a glass substrate, a non-alkali glass substrate, and the like. These can be used alone or in combination with each other.

The buffer layer BUF may be disposed on the substrate SUB. The buffer layer BUF may prevent metal atoms or impurities from diffusing from the substrate SUB to the first, second, and third transistors TR1, TR2, and TR3. In addition, the buffer layer BUF may improve the flatness of the surface of the substrate SUB when the surface of the substrate SUB is not uniform. For example, the buffer layer BUF may include an inorganic material such as silicon oxide, silicon nitride, silicon oxynitride, and the like. These can be used alone or in combination.

The first, second, and third active patterns ACT1, ACT2, and ACT3 may be disposed on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor. Each of the first, second, and third active patterns ACT1, ACT2, and ACT3 may include a source region, a drain region, and a channel region located between the source region and the drain region. The first, second, and third active patterns ACT1, ACT2, and ACT3 may be formed through the same process and may include the same material from each other.

The gate insulating layer GI may be disposed on the buffer layer BUF. The gate insulating layer GI may sufficiently cover the first, second, and third active patterns ACT1, ACT2, and ACT3, and may have a substantially flat upper surface without creating step around the first, second, and third active patterns ACT1, ACT2, and ACT3. In other embodiments, the gate insulating layer GI may cover the first, second, and third active patterns ACT1, ACT2, and ACT3, and may be disposed along the profile of each of the first, second, and third active patterns ACT1, ACT2, and ACT3 with a uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The first, second, and third gate electrodes GE1, GE2, and GE3 may be disposed on the gate insulating layer GI. The first gate electrode GE1 may overlap the channel area of the first active pattern ACT1, the second gate electrode GE2 may overlap the channel area of the second active pattern ACT2, and the third gate electrode GE3 may overlap the channel area of the third active pattern ACT3.

Each of the first, second, and third gate electrodes GE1, GE2, and GE3 may include metal, alloy metal nitride, conductive metal oxide, transparent conductive material, and the like.

Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide indium zinc oxide, and the like. In addition, examples of the metal nitride may include aluminum nitride (AlNₓ), tungsten nitride (WNₓ), chromium nitride (CrNₓ), and the like. These can be used alone or in combination with each other.

The first, second, and third gate electrodes GE1, GE2, and GE3 may be formed through the same process and may include the same material from each other.

The interlayer insulating layer ILD may be disposed on the gate insulating layer GI. The interlayer insulating layer ILD may sufficiently cover the first, second, and third gate electrodes GE1, GE2, and GE3 and may have a substantially flat upper surface without creating steps around the first, second, and third gate electrodes GE1, GE2, and GE3. In other embodiments, the interlayer insulating layer ILD may cover the first, second, and third gate electrodes GE1, GE2, and GE3 and may be disposed along the profile of each of the first, second, and third gate electrodes GE1, GE2, and GE3 with a uniform thickness. For example, the interlayer insulating layer ILD may include an inorganic material such as silicon oxide, silicon nitride, silicon carbide, silicon oxynitride, silicon oxycarbide, and the like. These can be used alone or in combination with each other.

The first, second, and third source electrodes SE1, SE2, and SE3 may be disposed on the interlayer insulating layer ILD. The first source electrode SE1 may be connected to the source region of the first active pattern ACT1 through a contact hole penetrating the gate insulating layer GI and the interlayer insulating layer ILD. The second source electrode SE2 may be connected to the source region of the second active pattern ACT2 through a contact hole penetrating the gate insulating layer GI and the interlayer insulating layer ILD. The third source electrode SE3 may be connected to the source region of the third active pattern ACT3 through a contact hole penetrating the gate insulating layer GI and the interlayer insulating layer ILD.

The first, second, and third drain electrodes DE1, DE2, and DE3 may be disposed on the interlayer insulating layer ILD. The first drain electrode DE1 may be connected to the drain region of the first active pattern ACT1 through a contact hole penetrating the gate insulating layer GI and the interlayer insulating layer ILD. The second drain electrode DE2 may be connected to the drain region of the second active pattern ACT2 through a contact hole penetrating the gate insulating layer GI and the interlayer insulating layer ILD. The third drain electrode DE3 may be connected to the drain region of the third active pattern ACT3 through a contact hole penetrating the gate insulating layer GI and the interlayer insulating layer ILD.

For example, each of the first, second, and third source electrodes SE1, SE2, and SE3 may include metal, alloy, metal nitride, conductive metal oxide, transparent conductive material, and the like. These can be used alone or in combination with each other. The first, second, and third d drain electrodes DE1, DE2, and DE3 may be formed through the same process as the first, second, and third source electrodes SE1, SE2, and SE3, and may include the same material as the first, second, and third source electrodes SE1, SE2, and SE3.

Accordingly, the first transistor TR1 including the first active pattern ACT1, the first gate electrode GE1, the first source electrode SE1, and the first drain electrode DE1 may be disposed on the substrate SUB. The second transistor TR2 including the second active pattern ACT2, the second gate electrode GE2, the second source electrode SE2, and the second drain electrode DE2 may be disposed on the substrate SUB. The third transistor TR3 including the third active pattern ACT3, the third gate electrode GE3, the third source electrode SE3, and the third drain electrode DE3 may be disposed on the substrate SUB.

The via insulating layer VIA may be disposed on the interlayer insulating layer ILD. The via insulating layer VIA may sufficiently cover the first, second, and third source electrodes SE1, SE2, and SE3 and the first, second, and third drain electrodes DE1, DE2, and DE3. The via insulating layer VIA may include an organic material. For example, the via insulating layer VIA may include an organic material such as phenolic resin, polyacrylates resin, polyimides resin, polyamides resin, siloxane resin, epoxy resin, and the like. These can be used alone or in combination with each other.

The first, second, and third pixel electrodes AE1, AE2, and AE3 may be disposed on the via insulating layer VIA. The first pixel electrodes AE1 may overlap the first light emitting area EA1, the second pixel electrode AE2 may overlap the third light emitting area EA3, and the third pixel electrode AE3 may overlap the second light emitting are EA2. The first pixel electrode AE1 may be connected to the first drain electrode DE1 through a contact hole penetrating the via insulating layer VIA. The second pixel electrode AE2 may be connected to the first drain electrode DE2 through a contact hole penetrating the via insulating layer VIA. Additionally, the third pixel electrode AE3 may be connected to the third drain electrode DE3 through a contact hole penetrating the via insulating layer VIA.

For example, each of the first, second, and third pixel electrodes AE1, AE2, and AE3 may include metal, alloy, metal nitride, conductive metal oxide, transparent conductive material, and the like. These can be used alone or in combination with each other. In an embodiment, each of the first, second, and third pixel electrodes AE1, AE2, and AE3 may have a stacked structure including ITO/Ag/ITO. The first, second, and third pixel electrodes AE1, AE2, and AE3 may be formed through the same process and may include the same material from each other. For example, each of the first, second, and third pixel electrodes AE1, AE2, and AE3 may operate as an anode.

The pixel defining layer PDL may be disposed on the via insulating layer VIA. The pixel defining layer PDL may overlap the non-light emitting area NEA. The pixel defining layer PDL may cover the edges of each of the first, second, and third pixel electrodes AE1, AE2, and AE3. In addition, an opening extending to and exposing a part of the upper surface of each of the first, second, and third pixel electrodes AE1, AE2, and AE3 may be defined in the pixel defining layer PDL. For example, the pixel defining layer PDL may be an inorganic material. In an embodiment, the pixel defining layer PDL may include an organic material such as an epoxy resin, a siloxane resin, and the like. They may be used alone or in combination with each other. In an embodiment, the pixel defining layer PDL may include an inorganic material and/or an organic material containing a light blocking material such as black pigment, black dye, and the like.

The first light emitting layer EML1 may be disposed on the first pixel electrode AE1. The second light emitting layer EML2 may be disposed on the second pixel electrode AE2. In addition, the third light emitting layer EML3 may be disposed on the third pixel electrode AE3. Each of the first, second, and third light emitting layers EML1, EML2, and EML3 may include a light emitting material that emits light of a preset color. For example, the first light emitting layer EML1 may include a light emitting material that emits red light, the second light emitting layer EML2 may include a light emitting material that emits blue light, and the third light emitting layer EML3 may include a light emitting material that emits green light. However, embodiments of the present disclosure are not limited thereto.

The first common electrode CE1 may be disposed on the first light emitting layer EML1 and the pixel defining layer PDL. The second common electrode CE2 may be disposed on the second light emitting layer EML2 and the pixel defining layer PDL. In addition, the third common electrode CE3 may be disposed on the third light emitting layer EML3 and the pixel defining layer PDL. The first, second, and third common electrodes CE1, CE2, and CE3 may be formed integrally. For example, each of the first, second, and third common electrodes CE1, CE2, and CE3 may include metal, alloy, metal nitride, conductive metal oxide, transparent conductive material, and the like. These can be used alone or in combination with each other. The first, second, and third common electrodes CE1, CE2, and CE3 may operate as cathode.

Accordingly, the first light emitting element LED1 including the first pixel electrode AE1, the first light emitting layer EML1, and the first common electrode CE1 may be disposed in the first light emitting area EA1 on the substrate SUB. The second light emitting element LED2 including the second pixel electrode AE2, the second light emitting layer EML2, and the second common electrode CE2 may be disposed in the third light emitting area EA3 on the substrate SUB. The third light emitting element LED3 including the third pixel electrode AE3, the third light emitting layer EML3, and the third common electrode CE3 may be disposed in the second light emitting area EA2 on the substrate SUB.

The first light emitting element LED1 may be electrically connected to the first transistor TR1, the second light emitting element LED2 may be electrically connected to the second transistor TR2, and the third light emitting element LED3 may be electrically connected to the third transistor TR3.

The encapsulation layer TFE may be disposed on the first, second, and third common electrodes CE1, CE2, and CE3. The encapsulation layer TFE may prevent impurities, moisture, external air, and the like from penetrating into the first, second, and third light emitting elements LED1, LED2, and LED3 from the outside. The encapsulation layer TFE may include at least one inorganic layer and at least one organic layer. For example, the inorganic layer may include silicon oxide, silicon nitride, silicon oxynitride, and the like. These can be used alone or in combination with each other. The organic layer may include a cured polymer such as polyacrylate.

The light transmission layer LTL may be disposed on the encapsulation layer TFE. Light emitted from the first, second, and third light emitting elements LED1, LED2, and LED3 may pass through the light transmission layer LTL. The light transmission layer LTL may have a substantially flat upper surface. In an embodiment, the light transmission layer LTL may include a transparent organic material. For example, the light transmission layer LTL may include a transparent organic material such as epoxy resin, siloxane resin, polyimide resin, photoresist, and the like. These can be used alone or in combination with each other.

For example, the light transmission layer LTL may contact the encapsulation layer TFE. That is, the light transmission layer LTL may have a lower surface directly contacting the encapsulation layer TFE. However, embodiments of the present disclosure are not limited thereto.

In an embodiment, a plurality of openings OP spaced apart from each other may be defined in the light transmission layer LTL. The plurality of openings OP may be spaced apart from each other along the second direction DR2. However, embodiments of the present disclosure are not limited thereto.

In an embodiment, the transparent layer LL may be disposed on the light transmission layer LTL. The transparent layer LL may contact an upper surface US of the light transmission layer LTL and extend to the inside of the openings OP to contact at least a part of a side surface SS of the light transmission layer LTL. For example, the transparent layer LL may contact the entire side surface SS of the light transmission layer LTL. However, embodiments of the present disclosure are not limited thereto.

For example, the transparent layer LL may also contact the encapsulation layer TFE. That is, the transparent layer LL may have a lower surface directly contacting the encapsulation layer TFE. However, embodiments of the present disclosure are not limited thereto.

In an embodiment, a lower surface facing the first, second, and third light emitting elements LED1, LED2, and LED3 of the transparent layer LL and a lower surface facing the first, second, and third light emitting elements LED1, LED2, and LED3 of the light transmission layer LTL may be located on the same plane. For example, the lower surface of the transparent layer LL in contact with the encapsulation layer TFE and the lower surface of the light transmission layer LTL in contact with the encapsulation layer TFE may be located on the same plane. However, embodiments of the present disclosure are not limited thereto.

The transparent layer LL may include a transparent inorganic material. For example, the transparent layer LL may include a silicon compound such as silicon oxide, silicon nitride, silicon oxynitride, and the like. In this case, an average thickness TH of the transparent layer LL may range from about 300 angstroms (Å) to about 3000 angstroms (Å). When the average thickness TH of the transparent layer LL is less than about 300 angstroms (Å), a part of the light transmission layer LTL may be removed in the process of forming the light control patterns LCP. It may be impossible due to the process to form the transparent layer LL with the average thickness TH exceeding about 3000 angstroms (Å).

In other embodiments, the transparent layer LL may include a conductive metal oxide such as indium gallium oxide, indium zinc oxide, indium tin oxide, indium zinc tin oxide, indium gallium zinc oxide, and the like. In this case, the average thickness TH of the transparent layer LL may range from about 30 angstroms (Å) to about 3000 angstroms (Å). When the average thickness TH of the transparent layer LL is less than about 30 angstroms, a part of the light transmission layer LTL may be removed in the process of forming the light control patterns LCP. It may be impossible in terms of the process to form the transparent layer LL with the average thickness TH exceeding about 3000 angstroms.

For example, the transparent layer LL may have a single-layer structure. In other embodiments, the transparent layer LL may have a multi-layer structure of two or more layers.

With respect to visible light, the refractive index of the light transmission layer LTL and the refractive index of the transparent layer LL may be substantially similar. In this case, the viewing angle may be effectively controlled. For example, with respect to visible light, when the refractive index of the light transmission layer LTL is about 1.5, the refractive index of the transparent layer LL may be about 1.4 to about 2.28.

The plurality of light control patterns LCP spaced apart from each other may be disposed on the encapsulation layer TFE. The light control patterns LCP may be surrounded by the light transmission layer LTL. Specifically, the light control patterns LCP may fill the openings OP, respectively. In an embodiment, the light control patterns LCP may overlap the non-light emitting area NEA and the first, second, and third light emitting areas EA1, EA2, and EA3. However, embodiments of the present disclosure are not limited thereto.

In an embodiment, each of the light control patterns LCP may include an organic material containing a light blocking material such as black pigment, black dye, and the like. However, embodiments of the present disclosure are not limited thereto.

Light emitted from the first, second, and third light emitting elements LED1, LED2, and LED3 may be incident on the light control patterns LCP or may pass through between the light control patterns LCP. Light incident on the light control patterns LCP may be reflected from the light control patterns LCP, or absorbed by the light control patterns LCP. For example, most of the light incident on the light control patterns LCP may be absorbed by the light control patterns LCP. Accordingly, the light control patterns LCP may control the viewing angle of the display device 100.

For example, when the display device 100 is a front emitting type, the light control patterns LCP may be disposed on the first, second, and third light emitting elements LED1, LED2, and LED3. In other embodiments, when the display device 100 is a bottom emitting type, the light control patterns LCP may be disposed under the first, second, and third light emitting elements LED1, LED2, and LED3.

In an embodiment, the light control patterns LCP may be spaced apart from each other in the second direction DR2, and each of the light control patterns LCP may extend in the first direction DR1 (see FIG. 5). However, embodiments of the present disclosure are not limited thereto.

In an embodiment, each of the light control patterns LCP may have a cross-sectional shape that becomes narrower as a distance from the first, second, and third light emitting elements LED1, LED2, and LED3 increases. For example, in this case, an angle θ formed between the side surfaces of each of the light control patterns LCP and the upper surface of the encapsulation layer TFE may be an acute angle. Here, the angle θ refers to the smaller angle among the angles formed between the side surfaces of each of the light control patterns LCP and the upper surface of the encapsulation layer TFE.

That is, due to the transparent layer LL, each of the light control patterns LCP may have a cross-sectional shape that becomes narrower as the distance from the first, second, and third light emitting elements LED1, LED2, and LED3 increases. Accordingly, the light efficiency of the display device 100 is improved, and the display device 100 may control the viewing angle more effectively.

In the process of forming the light control patterns LCP, an etch rate of the light control patterns LCP may be different from an etch rate of the transparent layer LL. In an embodiment, in the process of forming the light control patterns LCP, the etch rate of the light control patterns LCP may be greater than the etch rate of the transparent layer LL.

As the display device 100 includes light control patterns LCP, the display device 100 may not include a separate light blocking film that controls the viewing angle.

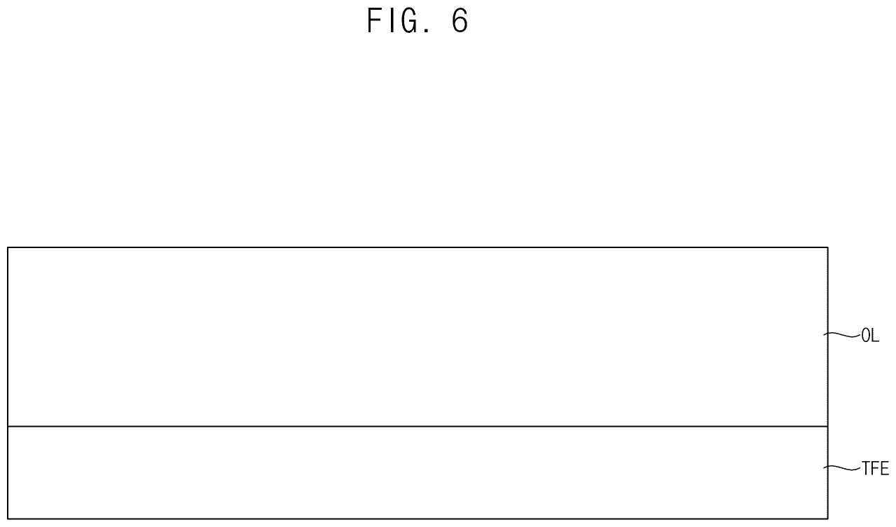

FIGS. 6, 7, 8, 9, 10, 11, 12, and 13 are cross-sectional views illustrating some steps of a method of manufacturing the display device 100 of FIGS. 3 and 4. Hereinafter, descriptions that overlap with the description of the display device 100 described with reference to FIG. 3 will be omitted or simplified.

Referring to FIGS. 3 and 6, the buffer layer BUF, the first, second, and third active patterns ACT1, ACT2, and ACT3, the gate insulating layer GI, the first, second, and third gate electrodes GE1, GE2, and GE3, the interlayer insulating layer ILD, the first, second, and third source electrodes SE1, SE2, and SE3, the first, second, and third drain electrodes DE1, DE2, and DE3, the via insulating layer VIA, the first, second, and third pixel electrodes AE1, AE2, and AE3, the pixel defining layer PDL, the first, second, and third light emitting layers EML1, EML2, and EML3, the first, second, and third common electrode CE1, CE2, and CE3, and the encapsulation layer TFE may be sequentially formed on the substrate SUB.

An organic layer OL may be formed on the encapsulation layer TFE. For example, the organic layer OL may be formed using a transparent organic material such as epoxy resin, siloxane resin, polyimide resin, photoresist, and the like.

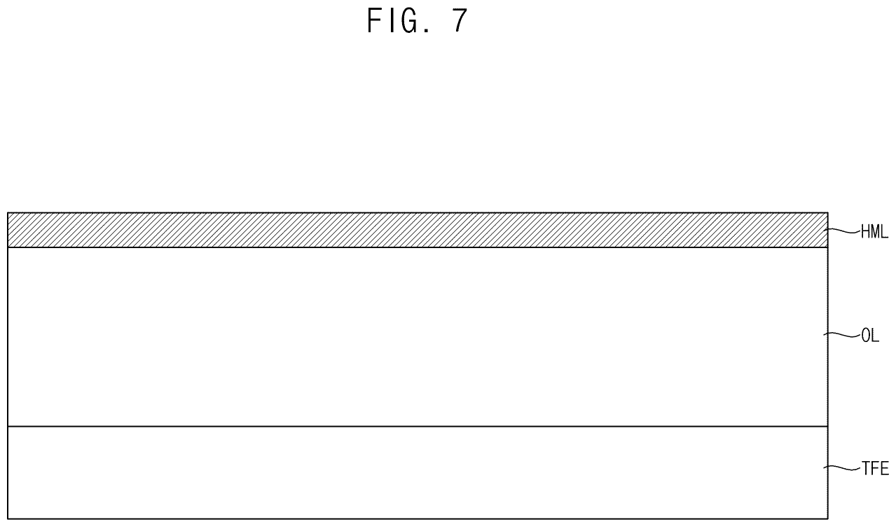

Referring to FIG. 7, a hard mask layer HML may be formed on the organic layer OL. The hard mask layer HML may be formed using a metal material. For example, the hard mask layer HML may be formed using a transparent oxide such as indium tin oxide (ITO) or indium zinc oxide (IZO). However, embodiments of the present disclosure are not limited thereto.

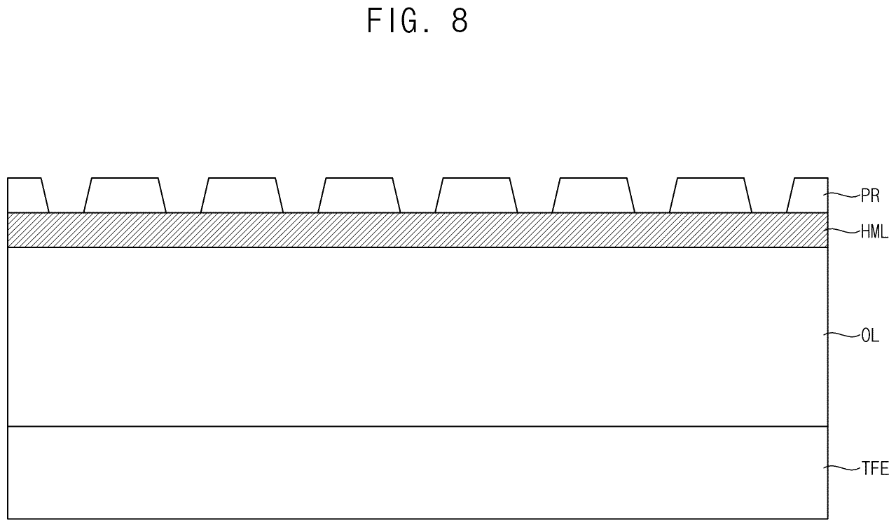

Referring to FIG. 8, photosensitive organic patterns PR may be formed on the hard mask layer HML. For example, photosensitive organic patterns PR may be formed using positive photoresist. In other embodiments, photosensitive organic patterns PR may be formed using negative photoresist.

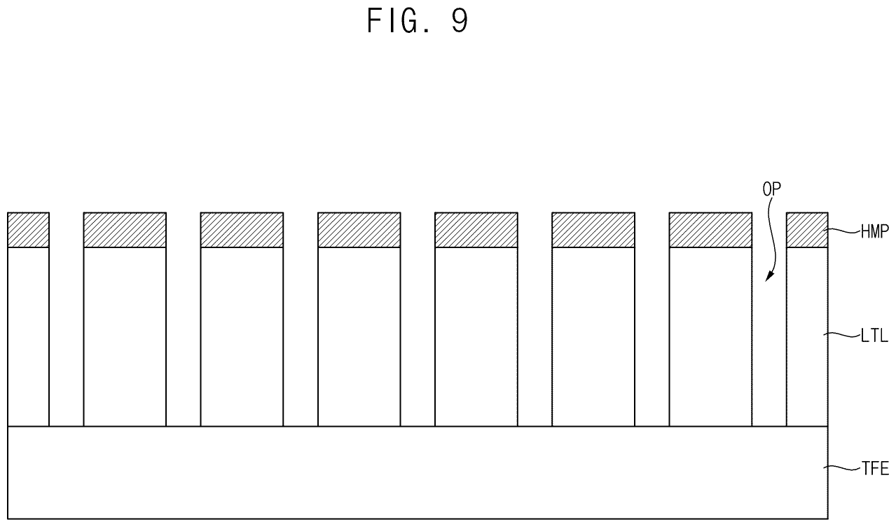

Referring to FIG. 9, as irradiating light to the organic layer OL and the hard mask layer HML, the organic layer OL and the hard mask layer HML may be patterned simultaneously by using the photosensitive organic patterns PR as a mask. In this case, a part of the organic layer OL and a part of the hard mask layer HML that do not overlap the photosensitive organic patterns PR may be removed. In an embodiment, the organic layer OL and the hard mask layer HML may be patterned through a dry etching process.

Accordingly, the light transmission layer LTL in which the plurality of openings OP spaced apart from each other are defined and a plurality of hard mask patterns HMP on the light transmission layer LTL may be formed. After the light transmission layer LTL and the plurality of hard mask patterns HMP are formed, the photosensitive organic patterns PR may be removed.

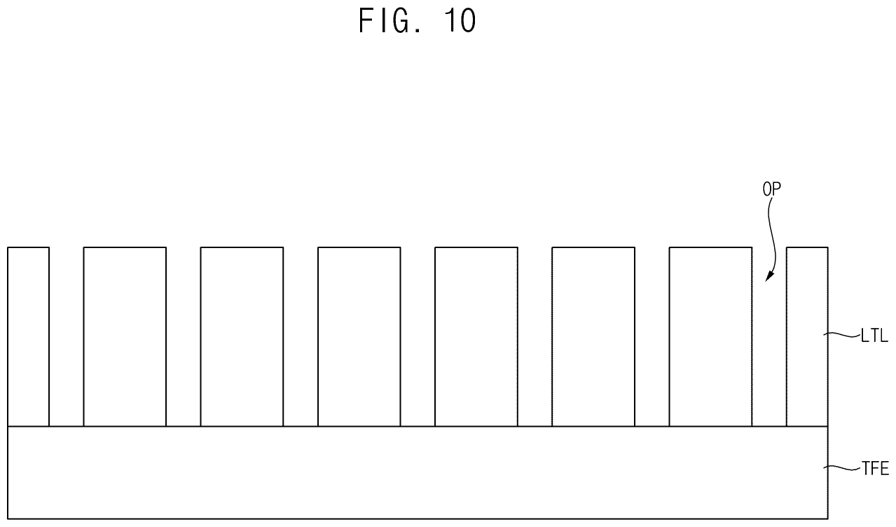

Referring to FIG. 10, after the photosensitive organic patterns PR are removed, the plurality of hard mask patterns HMP may be removed. For example, the plurality of hard mask patterns HMP may be removed through a dry etching process.

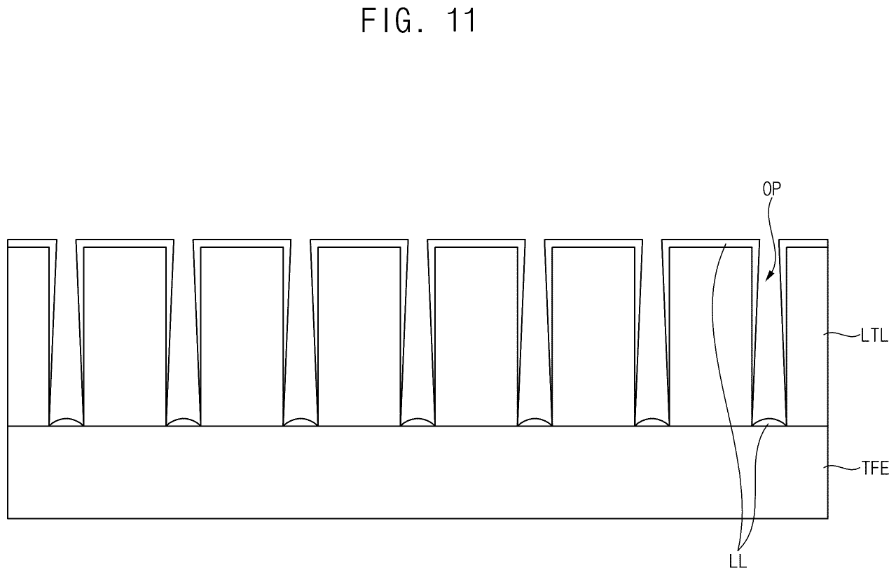

Referring to FIG. 11, the transparent layer LL may be formed on the encapsulation layer TFE and the light transmission layer LTL. Specifically, the transparent layer LL may be formed to contact the upper surface of the light transmission layer LTL, contact the side surface of the light transmission layer LTL, and extend to the inside of the openings OP.

For example, the transparent layer LL may be formed using a silicon compound. In this case, the transparent layer LL may be formed through chemical vapor deposition (CVD). In other embodiments, the transparent layer LL may be formed using a conductive metal oxide. In this case, the transparent layer LL may be formed through sputtering deposition. However, embodiments of the present disclosure are not limited thereto.

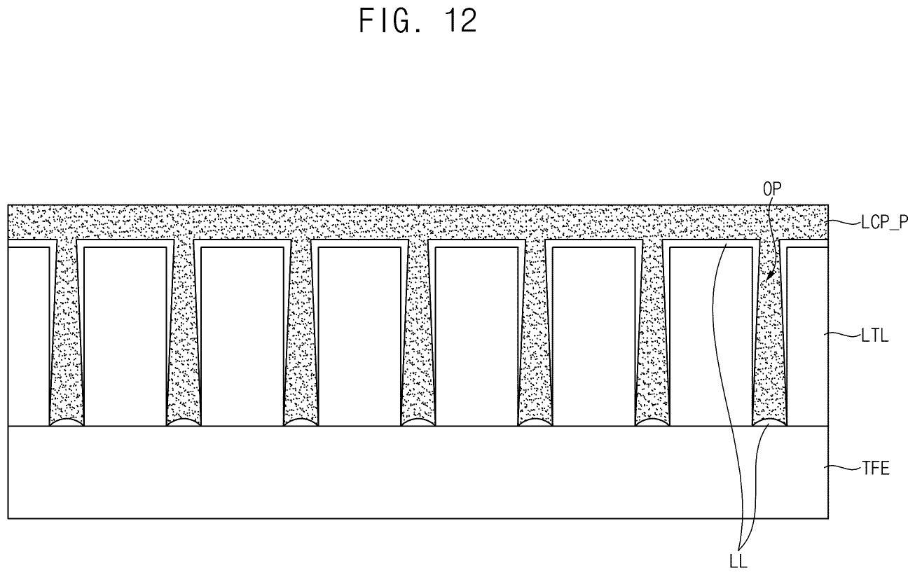

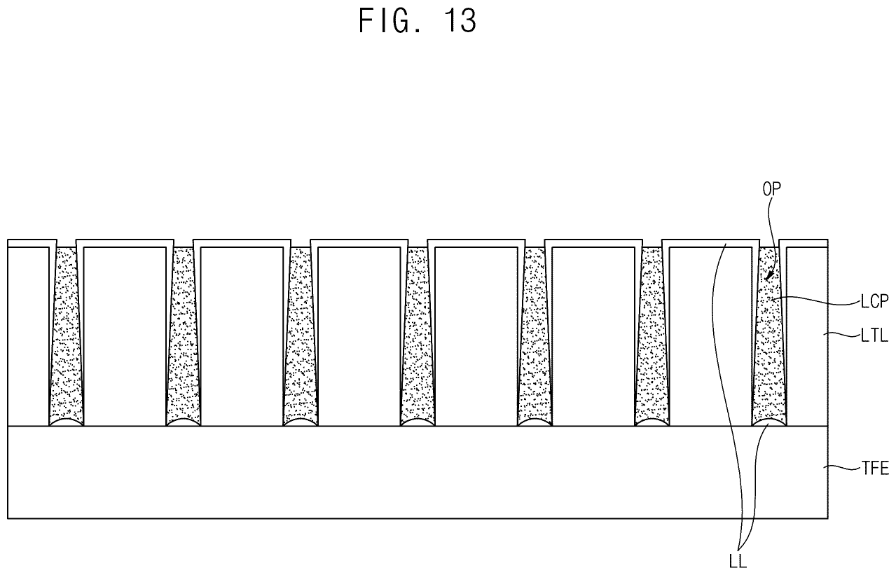

Referring to FIGS. 12 and 13, a preliminary light control pattern LCP_P may be formed on the transparent layer LL. The preliminary light control pattern LCP_P may be formed by filling the openings OP of the light transmission layer LTL. For example, the preliminary light control pattern LCP_P may be formed using an organic material containing a light blocking material such as black pigment, black dye, and the like.

A part of an upper part of the preliminary light control pattern LCP_P may be removed. In an embodiment, the portion of the upper part of the preliminary light control pattern LCP_P may be removed through an ashing process. Accordingly, the plurality of light control patterns LCP may be formed to respectively fill the plurality of openings OP.

As a result, the plurality of light control patterns LCP may be formed through an ashing process rather than a chemical mechanical polishing (CMP) process. Accordingly, mass productivity may be improved and process cost may be reduced.

In an embodiment, in the ashing process, the etch rate of the light control patterns LCP may be greater than the etch rate of the transparent layer LL. That is, in the ashing process, when the part of the upper part of the preliminary light control pattern LCP_P is removed, the light transmission layer LTL may not be removed.

Hereinafter, the effect of the present disclosure according to a Comparative Example and an Embodiment will be described.

In the Comparative Example, a light transmission layer including a polyimide resin was formed on the encapsulation layer, and a plurality of light control patterns surrounded by the light transmission layer and spaced apart from each other were formed using a known black matrix material. A width L of each of the plurality of light control patterns, a distance S between the plurality of adjacent light control patterns, a height H of each of the plurality of light control patterns, and an angle formed between the side surface of each of the plurality of light control patterns and the plane are shown in Table 1 below (see FIG. 4).

In the Embodiment, the light transmission layer LTL including a polyimide resin was formed on the encapsulation layer TFE, and the plurality of light control patterns LCP surrounded by the light transmission layer LTL and spaced apart from each other were formed using a known black matrix material. A width L of each of the plurality of light control patterns LCP, the distance S between the plurality of adjacent light control patterns LCP, a height H of each of the plurality of light control patterns LCP, and an angle formed between the side surface of each of the plurality of light control patterns LCP and the plane are shown in Table 1 below (see FIG. 4).

TABLE 1

| | |
|---|---|
| Comparative Example | Embodiment |

| | | | | |
|---|---|---|---|---|
| Width | 16 | μm | 16 | μm |
| Distance | 28.3 | μm | 28.3 | μm |
| Height | 92 | μm | 92 | μm |
| Angle | 90 | degrees | 87 | degrees |

Light efficiency and cut-off characteristic of the display device including the plurality of light control patterns and the light transmission layer satisfying the Comparative Example were measured. In addition, the light efficiency and cut-off characteristic of the display device 100 including the plurality of light control patterns LCP and the light transmission layer LTL satisfying the Embodiment were measured. Here, “light efficiency” refers to the transmittance of the display device from the front, and “cut-off characteristic” refers to the transmittance of the display device at a viewing angle of approximately 35 degrees based on a thickness direction of the display device.

As a result, referring to Table 2 below, it can be confirmed that the light efficiency of the display device 100 satisfying the Embodiment is higher than the light efficiency of the display device 100 satisfying the Comparative Example. In addition, it can be confirmed that the cut-off characteristics of the display device 100 satisfying the Embodiment are improved compared to the cut-off characteristics of the display device satisfying the Comparative Example.

TABLE 2

| | Comparative Example | Embodiment |
|---|---|---|
| Light efficiency (%) | 65.5 | 79.3 |
| Cut-off characteristic (%) | 3.2 | 1.5 |

Through this, it can be conformed that as each of the plurality of light control patterns LCP has the cross-sectional shape that becomes narrower as the distance from the light emitting element, e.g., the first, second, and third light emitting elements LED1, LED2, and LED3 of FIG. 3, increases, the light efficiency of the display device 100 is relatively high and the cut-off characteristic of the display device 100 is relatively improved. Here, improving the cut-off characteristic of the display device 100 refers to that the value of the cut-off characteristic of the display device 100 is relatively small.

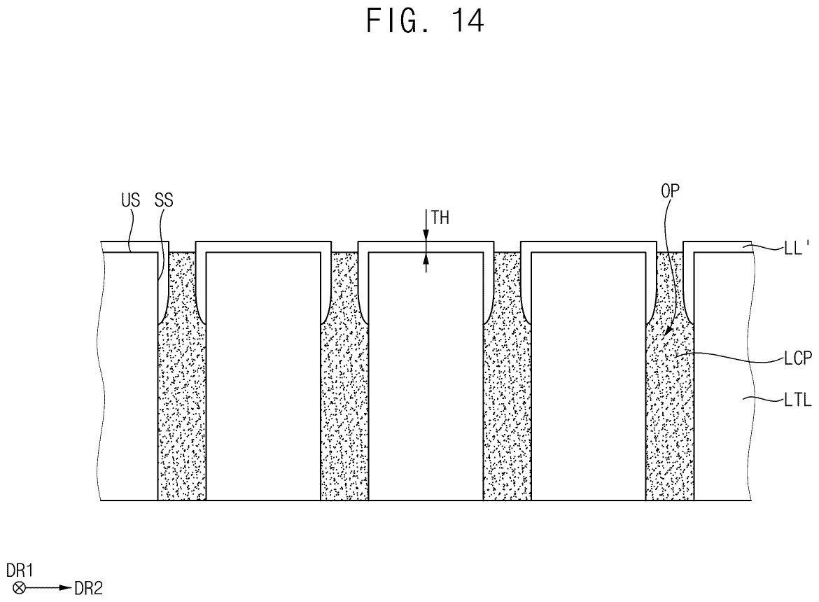

FIG. 14 is a cross-sectional view illustrating light control patterns LCP, a light transmission layer LTL, and a transparent layer LL′ of a display device according to an embodiment of the present disclosure. Hereinafter, descriptions that overlap with the light control patterns LCP, the light transmission layer LTL, and the transparent layer LL of the display device 100 described with reference to FIGS. 3 and 4 will be omitted or simplified.

Referring to FIGS. 3 and 14, the transparent layer LL′ may contact the upper surface US of the light transmission layer LTL and extend to the inside of the openings OP to contact the side surface SS of the light transmission layer LTL. In an embodiment, the transparent layer LL′ may contact only a part of the side surface SS of the light transmission layer LTL. That is, the transparent layer LL′ may contact the top of the side surface SS of the light transmission layer LTL and may not contact the bottom of the side surface SS of the light transmission layer LTL.

For example, the transparent layer LL′ may include a silicon compound such as silicon oxide, silicon nitride, silicon oxynitride, and the like. In this case, the average thickness TH of the transparent layer LL′ may range from about 300 angstroms (Å) to about 3000 angstroms (Å).

In other embodiments, the transparent layer LL′ may include a conductive metal oxide such as indium gallium oxide, indium zinc oxide, indium tin oxide, indium zinc tin oxide, indium gallium zinc oxide, and the like. In this case, the average thickness TH of the transparent layer LL′ may range from about 30 angstroms (Å) to about 3000 angstroms (Å).

For example, the transparent layer LL′ may have a single-layer structure. In other embodiments, the transparent layer LL′ may have a multi-layer structure of two or more layers.

Due to the transparent layer LL′, the width of the part of each of the light control patterns LCP contacting the transparent layer LL′ may be smaller than the width of the part of each of the light control patterns LCP not contacting the transparent layer LL′. Accordingly, the light efficiency of the display device 100 may be improved, and the display device 100 may control the viewing angle more effectively.

Referring again to FIGS. 1, 2, 3, 4, 5, 6, 7, 8, 9, 10, 11, 12, 13, and 14, the display device 100 according to an embodiment of the present disclosure may include the light transmission layer LTL in which the plurality of openings OP spaced apart from each other are defined, the transparent layer LL and LL′ contacting the upper surface US of the light transmission layer LTL and extending to the inside of the openings OP to contact at least a part of the side surface SS of the light transmission layer LTL, and the plurality of light control patterns LCP filling the openings OP, respectively. Accordingly, the light efficiency of the display device DD may be improved, and the display device DD may control the viewing angle more effectively. In addition, mass productivity may be improved and process cost may be reduced.

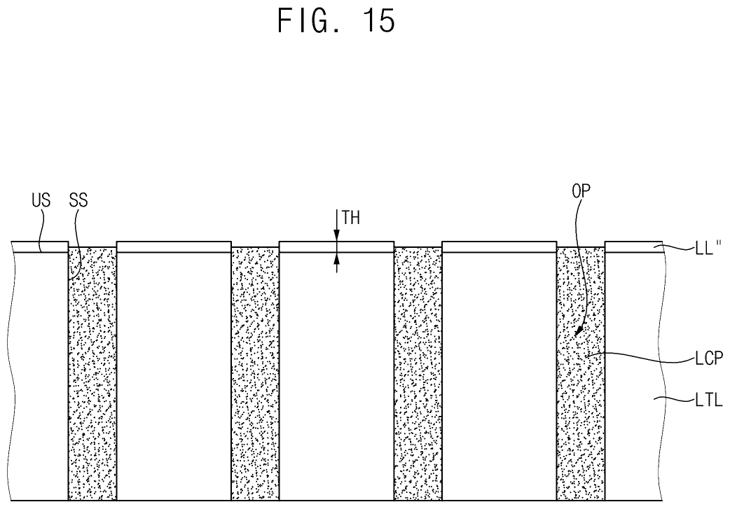

FIG. 15 is a cross-sectional view illustrating light control patterns LCP, a light transmission layer LTL, and a transparent layer LL″ of a display device according to an embodiment of the present disclosure. Hereinafter, descriptions that overlap with the light control patterns LCP, the light transmission layer LTL, and the transparent layer LL of the display device 100 described with reference to FIGS. 3 and 4 will be omitted or simplified.

Referring to FIG. 15, the transparent layer LL″ may be disposed on the light transmission layer LTL. That is, the transparent layer LL″ may be disposed only on the light transmission layer LTL and may not be disposed between the light transmission layer LTL. In other words, the transparent layer LL″ may contact the upper surface US of the light transmission layer LTL and may not contact the side surface SS of the light transmission layer LTL exposed by the openings OP.

For example, the transparent layer LL″ may include a silicon compound such as silicon oxide, silicon nitride, silicon oxynitride, and the like. In this case, the average thickness TH of the transparent layer LL″ may range from about 300 angstroms (Å) to about 3000 angstroms (Å).

In other embodiments, the transparent layer LL″ may include a conductive metal oxide such as indium gallium oxide, indium zinc oxide, indium tin oxide, indium zinc tin oxide, indium gallium zinc oxide, and the like. In this case, the average thickness TH of the transparent layer LL″ may range from about 30 angstroms (Å) to about 3000 angstroms (Å).

For example, the transparent layer LL″ may have a single-layer structure. In other embodiments, transparent layer LL″ may have a multi-layer structure of two or more layers.

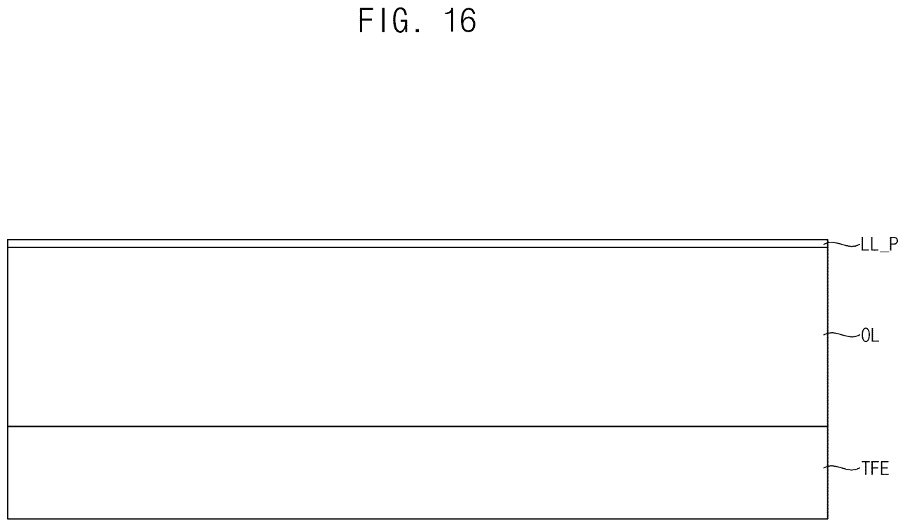

FIGS. 16, 17, 18, 19, 20, 21, and 22 are cross-sectional views for explaining some steps of a method of manufacturing the display device 100 of FIGS. 3 and 15. Hereinafter, descriptions that overlap with the description of the display device 100 described with reference to FIGS. 3 and 4 will be omitted or simplified.

Referring to FIG. 3, the buffer layer BUF, the first, second, and third active patterns ACT1, ACT2, and ACT3, the gate insulating layer GI, the first, second, and third gate electrodes GE1, GE2, and GE3, the interlayer insulating layer ILD, the first, second, and third source electrodes SE1, SE2, and SE3, the first, second, and third drain electrodes DE1, DE2, and DE3, the via insulating layer VIA, the first, second, and third pixel electrodes AE1, AE2, and AE3, the pixel defining layer PDL, the first, second, and third light emitting layers EML1, EML2, and EML3, the first, second, and third common electrode CE1, CE2, and CE3, and the encapsulation layer TFE may be sequentially formed on the substrate SUB.

Referring to FIG. 16, an organic layer OL may be formed on the encapsulation layer TFE. For example, the organic layer OL may be formed using a transparent organic material such as epoxy resin, siloxane resin, polyimide resin, photoresist, and the like.

A preliminary transparent layer LL_P may be formed on the organic layer OL. For example, the preliminary transparent layer LL_P may be formed using a silicon compound. In this case, the preliminary transparent layer LL_P may be formed through a chemical vapor deposition method. In other embodiments, the preliminary transparent layer LL_P may be formed using a conductive metal oxide. In this case, the preliminary transparent layer LL_P may be formed through sputtering deposition. However, embodiments of the present disclosure are not limited thereto.

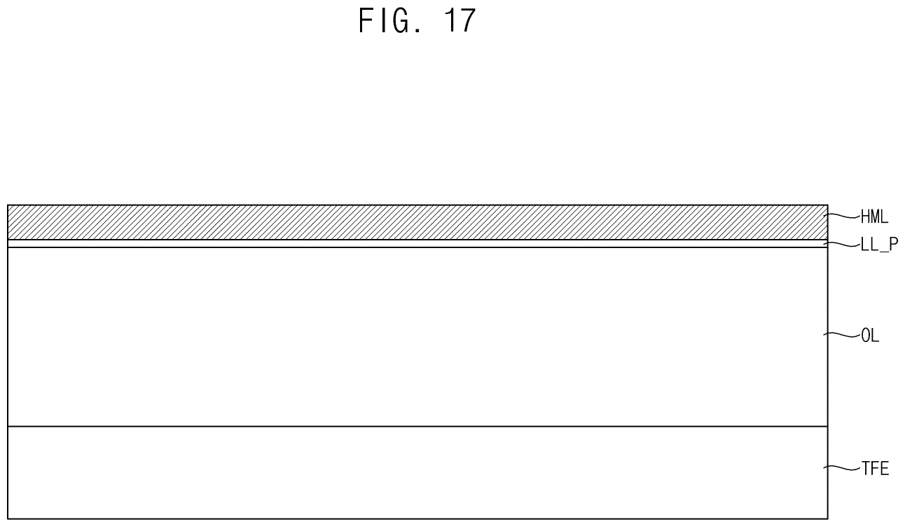

Referring to FIG. 17, a hard mask layer HML may be formed on the preliminary transparent layer LL_P. The hard mask layer HML may be formed using a metal material. For example, the hard mask layer HML may be formed using a transparent oxide such as indium tin oxide (ITO) or indium zinc oxide (IZO). However, embodiments of the present disclosure are not limited thereto.

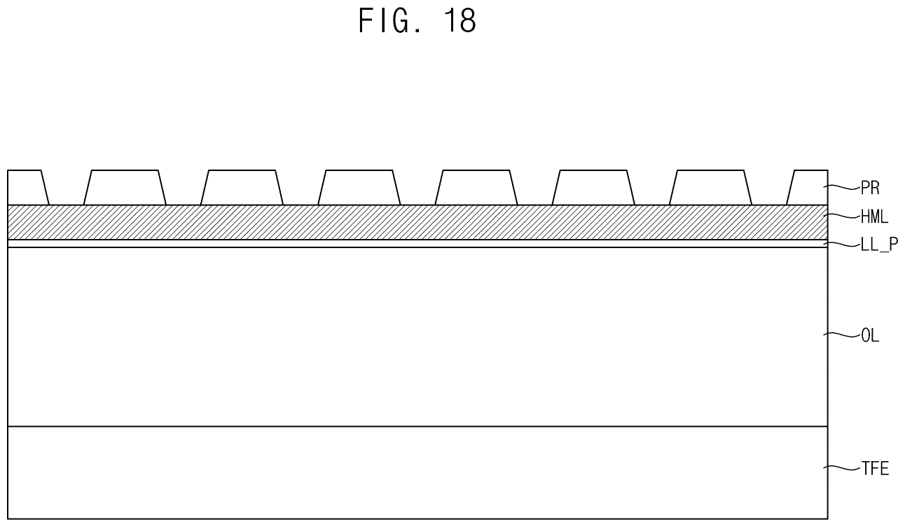

Referring to FIG. 18, photosensitive organic patterns PR may be formed on the hard mask layer HML. For example, the photosensitive organic patterns PR may be formed using positive photoresist. In other embodiments, the photosensitive organic patterns PR may be formed using negative photoresist.

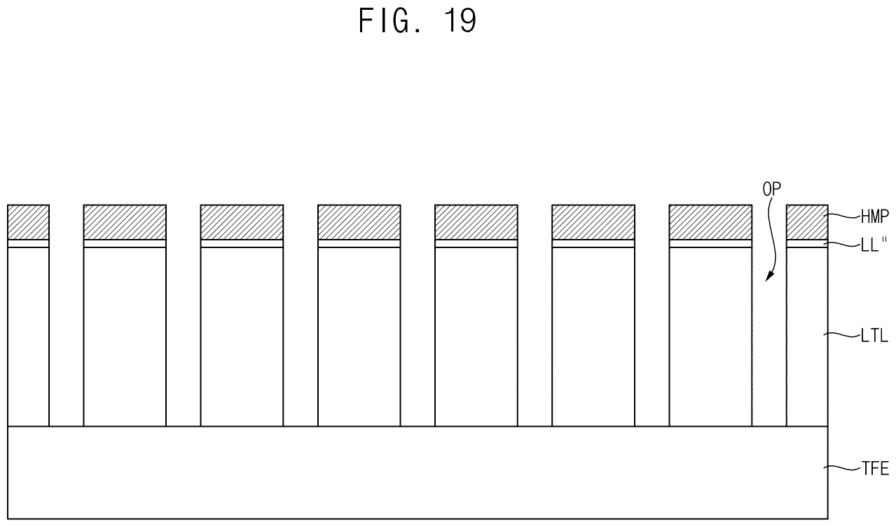

Referring to FIG. 19, as irradiating light to the organic layer OL, the organic layer OL, the preliminary transparent layer LL_P, and the hard mask layer HML may be patterned simultaneously using the photosensitive organic patterns PR as mask. In this case, a part of the organic layer OL, a part of the preliminary transparent layer LL_P, and a part of the hard mask layer HML that do not overlap the photosensitive organic patterns PR may be removed. In an embodiment, the organic layer OL, the preliminary transparent layer LL_P, and the hard mask layer HML may be patterned through a dry etching process.

Accordingly, the light transmission layer LTL in which the plurality of openings OP spaced apart from each other are defined, the transparent layer LL″ on the light transmission layer LTL, and a plurality of hard mask patterns HMP on the transparent layer LL″ may be formed. After the light transmission layer LTL, the transparent layer LL″, and the plurality of hard mask patterns HMP are formed, the photosensitive organic patterns PR may be removed.

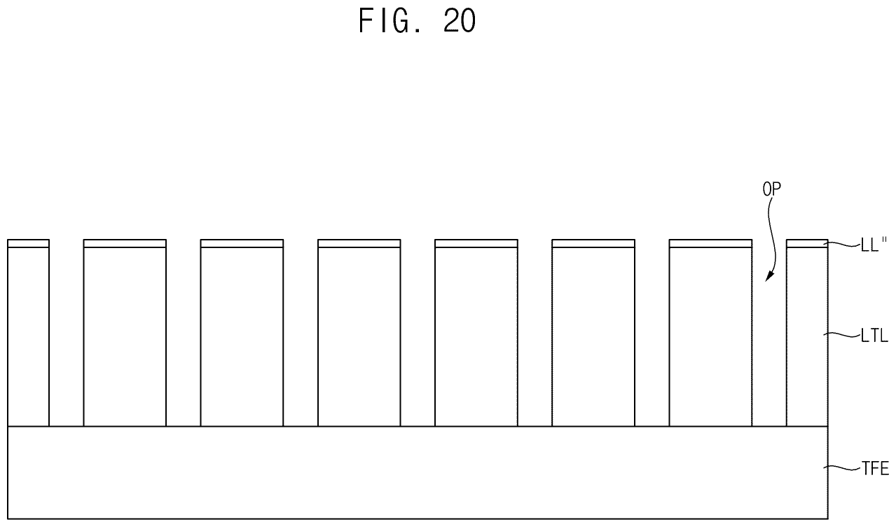

Referring to FIG. 20, in an embodiment, after the photosensitive organic patterns PR are removed, the hard mask patterns HMP may be removed. For example, the plurality of hard mask patterns HMP may be removed through a dry etching process. In an embodiment, the hard mask patterns HMP are not removed through a separate process, and the hard mask layer HML may be removed in the process of forming the light transmission layer LTL and the transparent layer LL″.

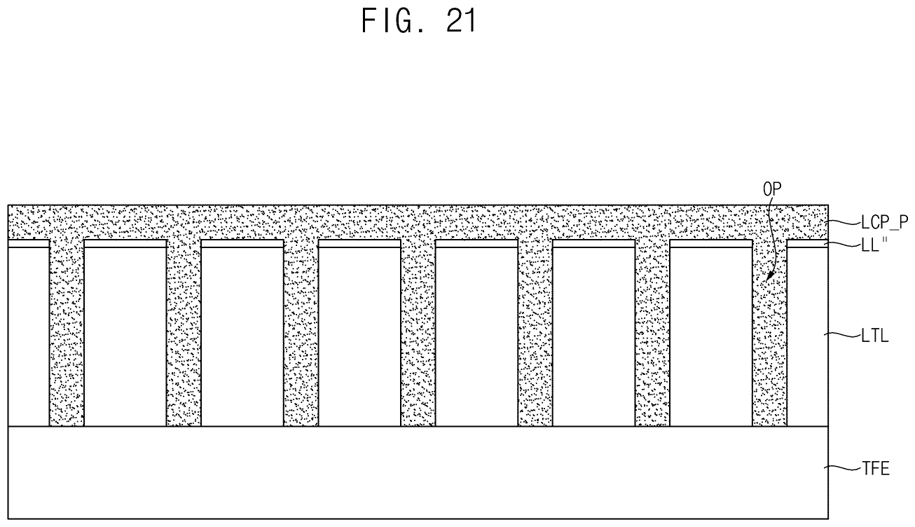

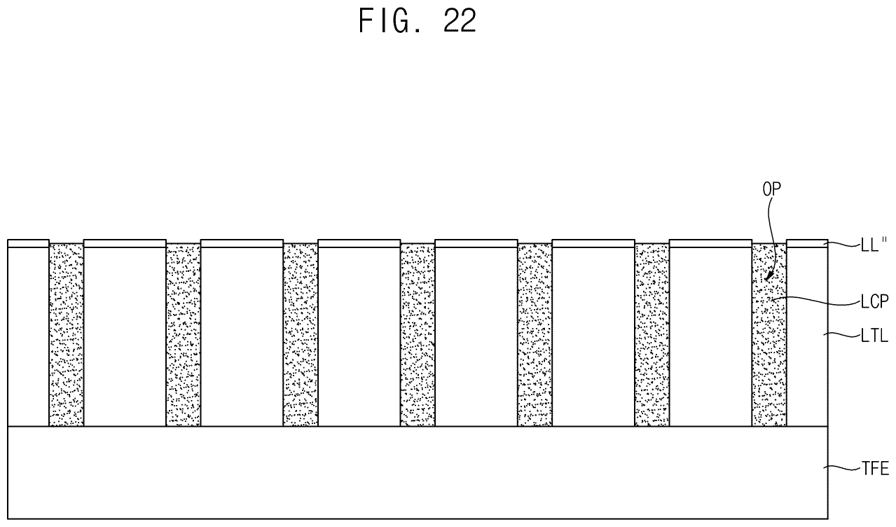

Referring to FIGS. 21 and 22, a preliminary light control pattern LCP_P may be formed on the transparent layer LL″. The preliminary light control pattern LCP_P may be formed by filling the openings OP of the light transmission layer LTL. For example, the preliminary light control pattern LCP_P may be formed using an organic material containing a light blocking material such as black pigment, black dye, and the like.

A part of the upper part of the preliminary light control pattern LCP_P may be removed. In an embodiment, the part of the upper part of the preliminary light control pattern LCP_P may be removed through an ashing process. Accordingly, the plurality of light control patterns LCP may be formed to respectively fill the plurality of openings OP.

As a result, the plurality of light control patterns LCP may be formed through an ashing process rather than a chemical mechanical polishing process. Accordingly, mass productivity may be improved and process cost may be reduced.

In an embodiment, in the ashing process, the etch rate of the light control patterns LCP may be greater than the etch rate of the transparent layer LL″. That is, in the ashing process, when the part of the upper part of the preliminary light control pattern LCP_P is removed, the light transmission layer LTL may not be removed.

Referring again to FIGS. 15, 16, 17, 18, 19, 20, and 21, the display device according to an embodiment of the present disclosure may include the light transmission layer LTL in which the plurality of openings OP spaced apart from each other are defined, the transparent layer LL″ contacting the upper surface US of the light transmission layer LTL and not contacting the side surface SS of the light transmission layer LTL, and the plurality of light control patterns LCP filling the transparent layer LL″, respectively. Accordingly, mass productivity may be improved and process cost may be reduced.

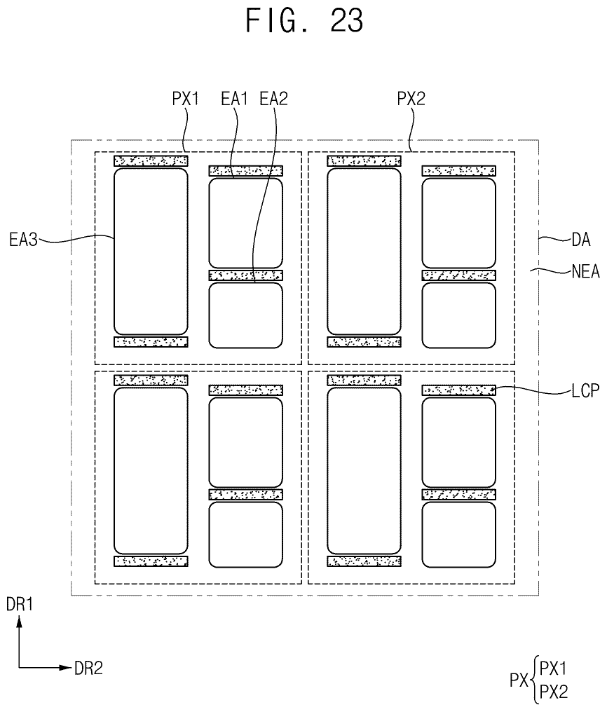

FIG. 23 is a plan view illustrating an example of light control patterns of FIG. 3.

Referring to FIG. 23, in an embodiment, the plurality of light control patterns LCP may overlap the non-light emitting area NEA and may not overlap the first, second, and third light emitting areas EA1, EA2, and EA3. However, embodiments of the present disclosure are not limited thereto.

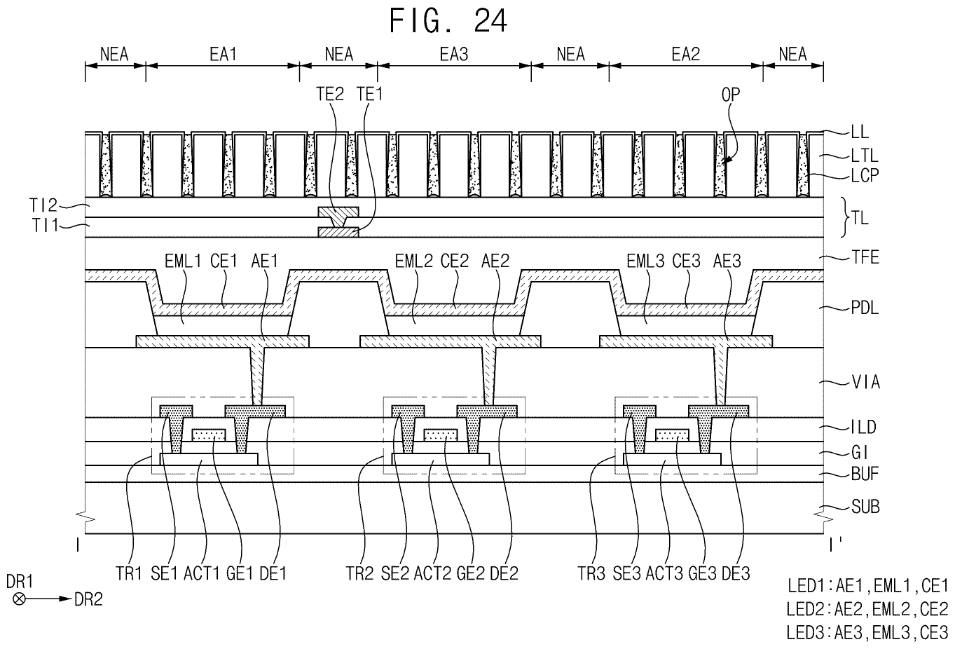

FIG. 24 is a cross-sectional view illustrating a display device according to an embodiment of the present disclosure.

Referring to FIG. 24, the display device according to an embodiment of the present disclosure may include a substrate SUB, a buffer layer BUF, first, second, and third transistors TR1, TR2, and TR3, a gate insulation. layer GI, an interlayer insulating layer ILD, a via insulating layer VIA, a pixel defining layer PDL, first, second, and third light emitting elements LED1, LED2, and LED3, an encapsulation layer TFE, a touch sensing layer TL, a plurality of light control patterns LCP, a transparent layer LL, and a light transmission layer LTL.

However, the display device described with reference to FIG. 24 may be substantially the same as or similar to the display device 100 described with reference to FIG. 3 except that it further includes the touch sensing layer TL. Therefore, hereinafter, overlapping descriptions will be omitted or simplified.

The touch sensing layer TL may be disposed on the encapsulation layer TFE.

Specifically, the touch sensing layer TL may be disposed between the encapsulation layer TFE and the light transmission layer LTL.

The touch sensing layer TL may include a first touch electrode TE1, a first touch insulating layer TI1 disposed on the first touch electrode TE1, a second touch electrode TE2 disposed on the first touch insulating layer TI1, and a second touch insulating layer TI2 disposed on the second touch electrode TE2. The second touch insulating layer TI2 may have a substantially flat upper surface. The second touch electrode TE2 may be connected to the first touch electrode TE1 through a contact hole penetrating the first touch insulating layer TI1. The touch sensing layer TL may function as an input means of the display device.

The plurality of light control patterns LCP, the transparent layer LL, and the light transmission layer LTL may be disposed on the touch sensing layer TL.

For example, the light transmission layer LTL may contact the touch sensing layer TL. That is, the light transmission layer LTL may have a lower surface directly contacting the touch sensing layer TL. However, embodiments of the present disclosure are not limited thereto.

For example, the transparent layer LL may contact the touch sensing layer TL. That is, the transparent layer LL may have a lower surface directly contacting the touch sensing layer TL. However, embodiments are not limited thereto.

In an embodiment, a lower surface facing the first, second, and third light emitting element LED1, LED2, and LED3 of the transparent layer LL and a lower surface facing the first, second, and third light emitting element LED1, LED2, and LED3 of the light transmission layer LTL may be located on the same plane. For example, the lower surface of the transparent layer LL contacting the touch sensing layer TL and the lower surface of the light transmission layer LTL contacting the touch sensing layer TL may be located on the same plane. However, embodiments of the present disclosure are not limited thereto.

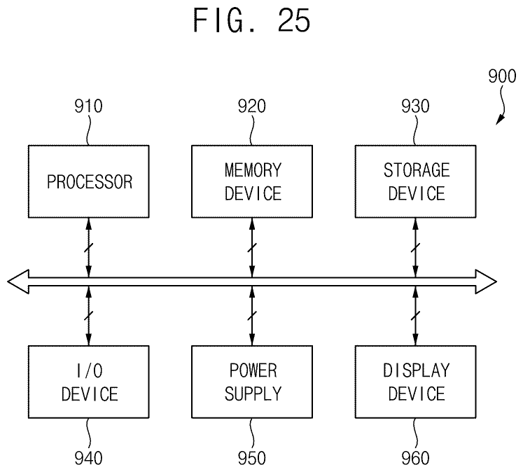

FIG. 25 is a block diagram illustrating an electronic device according to an embodiment of the present disclosure.

Referring to FIG. 25, in an embodiment, an electronic device 900 may include a processor 910, a memory device 920, a storage device 930, an input/output device 940, a power supply 950, and a display device 960. In this case, the display device 960 may correspond to the display device 100 described with reference to FIGS. 1 to 24. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a light emitting element disposed in a light emitting area on a substrate;
a light transmission layer disposed on the light emitting element and defining a plurality of openings spaced apart from each other;
a transparent layer contacting an upper surface of the light transmission layer and extending to an inside of the openings to contact at least a part of a side surface of the light transmission layer; and
a plurality of light control patterns filling the openings.

2. The display device of claim 1, wherein the transparent layer contacts an entire side surface of the light transmission layer.

3. The display device of claim 1, wherein the transparent layer contacts only a part of the side surface of the light transmission layer.

4. The display device of claim 1, wherein a lower surface of the transparent layer facing the light emitting element and a lower surface of the light transmission layer facing the light emitting element are located on a same plane.

5. The display device of claim 1, wherein the transparent layer includes a silicon compound.

6. The display device of claim 5, wherein an average thickness of the transparent layer ranges from about 300 angstroms (Å) to about 3000 angstroms (Å).

7. The display device of claim 1, wherein the transparent layer includes a conductive metal oxide.

8. The display device of claim 7, wherein an average thickness of the transparent layer ranges from about 30 angstroms (Å) to about 3000 angstroms (Å).

9. The display device of claim 1, wherein the transparent layer has a single-layer structure or a multi-layer structure.

10. The display device of claim 1, wherein an etch rate of the light control patterns is greater than an etch rate of the transparent layer.

11. The display device of claim 1, wherein each of the light control patterns has a cross-sectional shape that becomes narrower as a distance from the light emitting element increases.

12. The display device of claim 1, further comprising:
an encapsulation layer disposed between the light emitting element and the light transmission layer, and including at least one inorganic layer and at least one organic layer.

13. The display device of claim 12, further comprising:
a touch sensing layer disposed between the encapsulation layer and the light transmission layer.

14. The display device of claim 1, wherein the light control patterns include an organic material containing at least one selected from a group consisting of black pigment and black dye.

15. The display device of claim 1, wherein the light transmission layer includes a transparent organic material.

16. A method of manufacturing a display device, the method comprising:
forming a light emitting element in a light emitting area on a substrate;
forming a light transmission layer in which a plurality of openings spaced apart from each other are defined on the light emitting element;
forming a transparent layer contacting an upper surface of the light transmission layer and extending to an inside of the openings to contact at least a part of a side surface of the light transmission layer; and
forming a plurality of light control patterns filling the openings.

17. The method of claim 16, wherein in the forming the transparent layer,
the transparent layer is formed by chemical vapor deposition (CVD) or sputtering deposition.

18. The method of claim 16, wherein the transparent layer is formed using silicon oxide or conductive metal oxide.

19. The method of claim 16, wherein the forming the plurality of light control patterns includes:
forming a preliminary light control pattern filling the openings; and
forming the plurality of light control patterns by removing a part of an upper part of the preliminary light control pattern through an ashing process,
wherein the forming the light transmission layer includes:
forming an organic layer on the light emitting element;
forming a hard mask layer on the organic layer;
forming photosensitive organic patterns on the hard mask layer; and
simultaneously patterning the organic layer and the hard mask layer using the photosensitive organic patterns as a mask, and
wherein in the ashing process, an etch rate of the light control patterns is greater than an etch rate of the transparent layer.

20. An electronic device comprising:
a display device; and
a processor which controls the display device,
wherein the display device includes:
a light emitting element disposed in a light emitting area on a substrate;
a light transmission layer disposed on the light emitting element and defining a plurality of openings spaced apart from each other,
a transparent layer contacting an upper surface of the light transmission layer and extending to an inside of the openings to contact at least a part of a side surface of the light transmission layer, and
a plurality of light control patterns filling the openings.
